(19) United States
(12) Patent Application Publication
(10) Pub. No.: US 2026/0113050 A1
(43) Pub. Date: Apr. 23, 2026

(54) INCREASING ANALOG TO DIGITAL CONVERSION PRECISION

(71) Applicant: INTERNATIONAL BUSINESS MACHINES CORPORATION, ARMONK, NY (US)

(72) Inventors: Stefano Ambrogio, San Jose, CA (US); Pritish Narayanan, San Jose, CA (US); Geoffrey Burr, Cupertino, CA (US)

(21) Appl. No.: 18/923,739

(22) Filed: Oct. 23, 2024

(51) Int. Cl. H03M 1/06

(52) U.S. Cl. CPC H03M 1/0658

(57) ABSTRACT

Analog to digital conversion by converting a charge of a capacitor from an analog value to a first digital value and storing the first digital value. Further by adding an electrical charge to the capacitor, yielding an enhanced capacitor charge. Also by converting the enhanced capacitor charge from an analog value to a second digital value, determining an average of the first digital value and the second digital value, and providing the average as an output.

### FIELD OF THE INVENTION

The disclosure relates generally to systems and methods for increasing the precision of analog to digital conversion (ADC). The invention relates particularly to increasing ADC. precision by row reordering and double data sampling techniques.

### BACKGROUND

Analog-Artificial Intelligence (AI) includes performing parallel vector-matrix multiplications, with excitation vectors introduced onto multiple row-lines to perform multiply and accumulate (MAC) operations across an entire matrix of stored weights encoded into the conductance values of analog nonvolatile resistive memories.

The charge collected on the peripheral capacitor after the MAC operation is then converted into a digital representation using an Analog-to-Digital Converter (ADC). To get a good conversion, many bits of resolution are required, which often lead to area-and power-consuming circuits.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatuses and/or computer program products enable analog to digital conversion with an increased precision.

Aspects of the invention disclose methods, systems and computer readable media associated with increasing analog to digital conversion by converting a capacitor charge from an analog value to a first digital value, storing the first digital value, adding an electrical charge to the capacitor, yielding an enhanced capacitor charge, converting the enhanced capacitor charge from an analog value to a second digital value, determining an average of the first digital value and the second digital value, and providing the average as an output.

Aspects of the invention disclose methods, systems and computer readable media associated with increasing analog to digital conversion by determining a mean vale for each row of a first matrix of values comprising a plurality of rows according to absolute values of weights in the row, yielding a plurality of mean values, ordering the rows of the matrix according to the plurality of mean values, programming a tile of analog memory cells according to values of the ordered rows, performing a multiply and accumulate (MAC) operation to each row of the tile, accumulating charge on a capacitor according to the MAC operations, converting an analog charge of the capacitor to a digital value, and storing the digital value.

Aspects of the invention disclose systems associated with increasing analog to digital conversion, the systems including an array of analog memory cells, an analog current source disposed in parallel with rows of the array, a capacitor dispose in series with the array and the analog current source, an analog to digital converter disposed to read the charge of the capacitor, a digital memory disposed to receive the ADC output, and a digital processor disposed to receive ADC and digital memory output.

### BRIEF DESCRIPTION OF THE DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1 provides a schematic illustration of a computing environment, according to an embodiment of the invention.

FIG. 2 provides a flowchart depicting an operational sequence, according to an embodiment of the invention.

FIG. 3 provides a flowchart depicting an operational sequence, according to an embodiment of the invention.

FIG. 4 provides a schematic illustration of system details according to an embodiment of the invention.

### DETAILED DESCRIPTION

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

Hardware accelerators for deep learning include the ability to store large arrays of data and to accurately execute Multiple - Accumulate operations on that data in place. MAC operations yield an accumulated charge on a device edge capacitor. Systems then perform an analog-to-digital conversion on this charge to obtain the MAC result. Disclosed embodiments enable an increase in the precision of the ADC performance without an accompanying increase in the size or power requirements of the ADC itself. This in turn enables an improvement in the weight precision used in the deep learning accelerator.

Aspects of the present invention relate generally to analog AI accelerators and particularly to improving the precision of ADC for such accelerators. In embodiments, An AI accelerator converts a capacitor charge from an analog value to a first digital value and stores the first digital value in a digital memory. The system then adds charge to the previously read capacitor and converts the new analog charge value to a digital value. The system then determines the average for the two values and provides the average value as an output. By this process, the embodiments increase the precision of the ADC by one bit without any increase in the size or power requirements of the ADC on the device. Embodiments may also alter the order of the data programmed onto accelerator memory tiles prior to processing the data in order to enhance the precision by reducing the “noise” in the data. Noise reduction is accomplished by pre-sorting the data and ordering it according to value to reduce the variability in the data loaded onto the accelerator memory tiles. In this way the charge values converted from analog to digital better reflect the data which was processed. Embodiments may be used in tandem to further improve analog AI accelerator performance.

In accordance with aspects of the invention there is a method for automatically improving the bit precision of ADC aspects of analog AI accelerators. In embodiments, an AI accelerator converts a capacitor charge from an analog value to a first digital value and stores the first digital value in a digital memory. The method then adds charge to the previously read capacitor and converts the new analog charge value to a digital value. The method then determines the average for the two values and provides the average value as an output. By this process, the embodiments increase the precision of the ADC by one bit without any increase in the size or power requirements of the ADC on the device. Embodiments may also alter the order of the data programmed onto accelerator memory tiles prior to processing the data in order to enhance the precision by reducing the “noise” in the data. Noise reduction is accomplished by pre-sorting the data and ordering it according to value to reduce the variability in the data loaded onto the accelerator memory tiles. In this way the charge values converted from analog to digital better reflect the data which was processed. Embodiments may be used in tandem to further improve analog AI accelerator performance.

Aspects of the invention provide an improvement in the technical field of analog AI accelerators. Conventional QA systems utilize analog to digital converters. Increasing the precision of such ADC devices typically requires increasing the size of the ADC to add additional bits. In disclosed embodiments, an AI accelerator converts a capacitor charge from an analog value to a first digital value and stores the first digital value in a digital memory. The method then adds charge to the previously read capacitor and converts the new analog charge value to a digital value. The method then determines the average for the two values and provides the average value as an output. By this process, the embodiments increase the precision of the ADC by one bit without any increase in the size or power requirements of the ADC on the device. Embodiments may also alter the order of the data programmed onto accelerator memory tiles prior to processing the data in order to enhance the precision by reducing the “noise” in the data. Noise reduction is accomplished by pre-sorting the data and ordering it according to value to reduce the variability in the data loaded onto the accelerator memory tiles. In this way the charge values converted from analog to digital better reflect the data which was processed. Embodiments may be used in tandem to further improve analog AI accelerator performance.

Aspects of the invention also provide an improvement to computer functionality. In particular, implementations of the invention are directed to a specific improvement to the precision of AI accelerators by improving ADC precision and reducing noise in data. In disclosed embodiments, an AI accelerator converts a capacitor charge from an analog value to a first digital value and stores the first digital value in a digital memory. The method then adds charge to the previously read capacitor and converts the new analog charge value to a digital value. The method then determines the average for the two values and provides the average value as an output. By this process, the embodiments increase the precision of the ADC by one bit without any increase in the size or power requirements of the ADC on the device. Embodiments may also alter the order of the data programmed onto accelerator memory tiles prior to processing the data in order to enhance the precision by reducing the “noise” in the data. Noise reduction is accomplished by pre-sorting the data and ordering it according to value to reduce the variability in the data loaded onto the accelerator memory tiles. In this way the charge values converted from analog to digital better reflect the data which was processed. Embodiments may be used in tandem to further improve analog AI accelerator performance.

In an embodiment, one or more components of the system can employ hardware and/or software to solve problems that are highly technical in nature. In embodiments, an AI accelerator converts a capacitor charge from an analog value to a first digital value and stores the first digital value in a digital memory. Embodiments then add charge to the previously read capacitor and converts the new analog charge value to a digital value. The method then determines the average for the two values and provides the average value as an output. By this process, the embodiments increase the precision of the ADC by one bit without any increase in the size or power requirements of the ADC on the device. Embodiments may also alter the order of the data programmed onto accelerator memory tiles prior to processing the data in order to enhance the precision by reducing the “noise” in the data. Noise reduction is accomplished by pre-sorting the data and ordering it according to value to reduce the variability in the data loaded onto the accelerator memory tiles. In this way the charge values converted from analog to digital better reflect the data which was processed. Embodiments may be used in tandem to further improve analog AI accelerator performance. These solutions are not abstract and cannot be performed as a set of mental acts by a human due to the processing capabilities needed to facilitate ADC precision improvement, for example. Further, some of the processes performed may be performed by a specialized computer for carrying out defined tasks related to enhancing analog AI accelerator performance. For example, a specialized computer can be employed to carry out tasks related to processing analog data or the like.

In one embodiment, a computer implemented method for analog to digital conversion includes converting a capacitor charge from an analog value to a first digital value and storing the first digital value. The method further includes adding an electrical charge to the capacitor, yielding an enhanced capacitor charge. And then converting the enhanced capacitor charge from an analog value to a second digital value. The method further includes determining an average of the first digital value and the second digital value and providing the average as an output. This method advantageously increases the precision of the analog to digital conversion by one bit without increasing the size of the ADC circuit.

In one embodiment, the computer method further includes determining a mean vale for each row of a first matrix of values comprising a plurality of rows according to absolute values of weights in the row, yielding a plurality of mean values, ordering the rows of the matrix according to the plurality of mean values, programming a tile of analog memory cells according to values of the ordered rows, performing a multiply and accumulate (MAC) operation to each row of the tile, accumulating charge on the capacitor according to the MAC operations. These steps advantageously reduce any signal noise in the analyzed data providing an improvement in output precision.

In one embodiment, the computer method also includes ordering the rows from a largest magnitude mean value to a smallest magnitude mean value. This step advantageous groups data according to magnitude and reduces overall data set noise when measurements are performed.

In one embodiment, the computer method also includes programming a plurality of tiles of analog memory cells according to values of the ordered rows, performing a multiply and accumulate (MAC) operation to each row of the tiles, accumulating charge on a capacitor for each tile of the plurality according to the MAC operations, converting the charge on the capacitor for each tile to a per tile digital value, summing the per tile digital values, and providing the sum as an output. These steps offer the advantage of handling and processing data sets which exceed the size of the available analog processing tiles by mapping data across multiple tiles for processing.

In one embodiment, the computer method also includes the additional electrical charge comprising about half a bin of charge. Adding about half a bin of charge provides a sufficient change in charge that a second ADC followed by an averaging of the two measured charges realizes a precision increase of one bit.

In one embodiment, the computer method also includes determining the additional according to an analog to digital converter precision. The determination of the additional charge depends upon the initial precision of the ADC. Additional charge of about one half the least significant digit of the initial ADC precision may be added.

In one embodiment, the computer method also includes adding an electrical charge to the capacitor, yielding an enhanced capacitor charge using an analog current source. This steps advantageously enhances the charge of the capacitor using circuitry having small area and power requirements.

In one embodiment, the computer method also includes the analog current source comprising read-only-memory (ROM). ROM may be easily added to the device without significant area or power requirements.

In one embodiment, the computer method also includes adding an electrical charge to the capacitor, yielding an enhanced capacitor charge comprises applying a voltage to a resistor in a circuit with the capacitor. This step easily adds the required charge to the capacitor.

In one embodiment, the computer method also includes storing the first digital value comprises storing the first digital value in a digital memory. This step advantageously utilizes available digital memory for storage of the value.

In one embodiment, the computer method also includes applying an excitation voltage to an array of analog memory cells and accumulating the charge resulting from the excitation voltage in the capacitor. These steps provide a simple means for processing the values of the analog memory cells of the tile.

In one embodiment, the computer method also includes mapping values from a data set to cells of the array. This step advantageously maps data of interest to the analog tile for processing.

In one embodiment, the computer method also includes storing the second digital value. This step advantageously utilizes available digital memory to store and preserve the second digital value for later use.

In one embodiment, the computer method also includes determining the average of the first digital value and the second digital value using a digital processor. This step leverages the available digital processing to calculate the desired average value.

A computer implemented method for analog to digital conversion includes determining a mean vale for each row of a first matrix of values comprising a plurality of rows according to absolute values of weights in the row, yielding a plurality of mean values, ordering the rows of the matrix according to the plurality of mean values, programming a tile of analog memory cells according to values of the ordered rows, performing a multiply and accumulate (MAC) operation to each row of the tile, accumulating charge on a capacitor according to the MAC operations, converting an analog charge of the capacitor to a digital value, and storing the digital value.

In one embodiment, the computer method also includes ordering the rows from a largest magnitude mean value to a smallest magnitude mean value. This step advantageous groups data according to magnitude and reduces overall data set noise when measurements are performed.

In one embodiment, the computer method also includes programming a plurality of tiles comprising analog memory cells according to values of the ordered rows, performing a multiply and accumulate (MAC) operation to each row of the tiles, accumulating charge on a capacitor for each tile of the plurality according to the MAC operations, converting the charge on the capacitor for each tile to a per-tile digital value, summing the per tile digital values, storing the sum of the per-tile digital values, and providing the sum as an output. These steps offer the advantage of handling and processing data sets which exceed the size of the available analog processing tiles by mapping data across multiple tiles for processing.

In one embodiment, a system for analog to digital conversion: the system includes an array of analog memory cells, an analog current source disposed in parallel with rows of the array, a capacitor dispose in series with the array and the analog current source, an analog to digital converter disposed to read the charge of the capacitor, a digital memory disposed to receive the ADC output, and a digital processor disposed to receive ADC and digital memory outputs. This system provides the advantage of enabling an increased ADC precision without expanding the size of the ADC itself.

In one embodiment of the system, the analog current source comprises a row of read only memory (ROM). ROM provides a low area and power requirement analog current source.

In one embodiment of the system the analog memory cells comprise phase change memory (PCM) cells. PCM cells offer the capacity to store analog data values.

In one embodiment, after mapping data values to the memory cells of an analog memory tile, the cells are read by the system. Reading the cells includes performing a Multiply and Accumulate (MAC) operation across each row of the tile by applying a read voltage to the row of cells. The MAC operation produces an electrical charge related to the stored content of the cells of the row. The charge is stored in an edge capacitor of the tile. Methods then read and convert the analog charge stored in the capacitor to a digital value using an ADC circuit. Methods then store the ADC digital output in a digital memory such as volatile memory 112. In this embodiment, the method then adds an additional charge to the capacitor using an analog current source.

The analog current source may comprise Read-Only-Memory (ROM), such as a row of ROM disposed in parallel with the rows of the analog cells of the tile. Applying a voltage to the row of ROM adds the additional charge to the capacitor. After this charge is added, the ADC again reads and converts the charge stored in the capacitor to a digital value. The method may then store the additional value from the ADC associated with the new charge of the capacitor. After reading and converting the new charge value, methods average the digital outputs for the initial and new charge values, determine the average of the two values using a digital processor, and store and provide the average value as an output.

As an example, an initial charge may have a value of 0.43 microfarads (μF), with a digital conversion output value of 0. Embodiments may then add a charge of 0.5 to the capacitor, raising the charge value to 0.93, with a digital conversion value of 1. The average of the two values is then 0.5, effectively adding a significant digit or bit to the precision of the ADC for the data.

In one embodiment, methods determine the amount of additional charge to add to the capacitor according to the precision of the ADC. In this embodiment, methods add about one half of a bin of the precision of the ADC. For an ADC having n bits of resolution, 2ⁿ bins are required with the width of each bin being FSR/2ⁿ, where FSR is the full-scale range of the ADC.

Embodiments add the charge by applying an excitation voltage across the resistance of the row of ROM. Tuning the actual applied excitation voltage yields a range of applied voltages such that the actual applied voltage approximates the desired half a bin but may vary from the desired value.

In one embodiment, methods reduce the variability across local portions of the data set, or the noise of the local portion, by mapping the data set to analog memory tiles of the system according to the mean absolute value of the weight data of each row of a matrix corresponding to the data weights. In this embodiment, methods determine a mean absolute value for each row of weights of the data. Methods then re-order the rows of the data matrix such that the rows disposed in order from the row having the largest magnitude mean absolute value, to the row having the lowest magnitude mean absolute value. Methods then map, or program, the re-ordered weight data to one or more analog memory cell tiles. The number of tiles to which methods map the data depends upon the amount of data. As an example, an analog tile may comprise 3072 rows of cells, each row comprising 768 columns of cells. Data sets exceeding the capacity of this array of memory cells are mapped to additional analog memory tiles for processing. After mapping data to the tile(s) methods process the data as described above, performing MAC operations upon rows, accumulating charge and performing ADC upon the accumulated charge. Embodiments practicing reordering the data rows of the data set prior to mapping the data to analog memory tiles and processing the data after reordering the rows exhibit a reduction in the standard deviation of the results distribution. In one embodiment, the standard deviation diminished from 1.07 to 1.02.

In one embodiment, methods determine an ADC output for the accumulated charge for each tile, then summing the ADC output for each tile to determine a final value for the entire data set of weights which have been mapped to the set of tiles.

In one embodiment, method perform both the process of re-ordering the data prior to mapping the data to tiles and also the process of double-sampling the accumulated charge described above wherein the charge is samples and ADC is performed, then chare is added to the capacitor and ADC is performed again with methods then determining an average of the two ADC outputs.

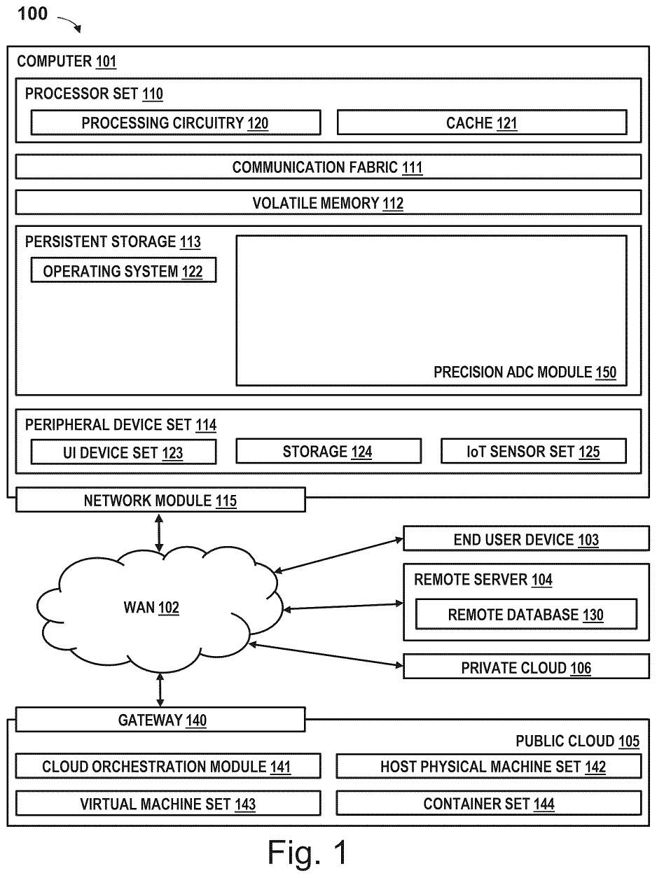

As shown in FIG. 1, computing environment 100 contains an example of an environment for the execution of at least some of the computer code involved in performing the inventive methods, such as increasing the precision of analog to digital conversion, block 150. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101. Volatile memory 112 may comprise one or more tiles of analog memory such as phase-change memory, or resistive-random-access-memory. Volatile memory 112 may further comprise one or more edge capacitors configured to gather charge as memory cell values are read, and analog-to-digital converters, configured to convert the accumulated charge of the edge capacitor(s) to digital values.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer, and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

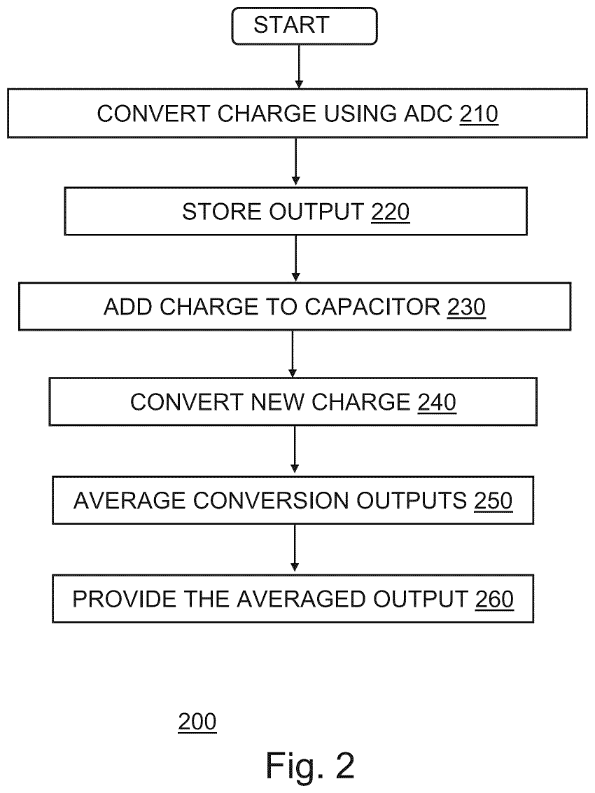

FIG. 2 provides a flowchart 200, illustrating exemplary activities associated with the practice of the disclosure. After program start, at step 210, embodiments convert the charge of an edge capacitor from analog to a first digital value using an ADC. In one embodiment, an analog memory tile hold data associated with node weights of an artificial intelligence network, such as a deep neural network. In this embodiment, the node weights are mapped to the memory cells of the analog memory tile and processed. The processing includes applying a read excitation voltage to each row of memory sells and accumulating charge in an edge capacitor according to the analog resistance values stored in the cells of the row.

At step 220, embodiments store the output of the ADC in digital memory such as volatile memory 112, accessible by the system processor set 110.

At step 230, embodiments apply an excitation voltage to an analog current source, such as a row of ROM cells in parallel with the analog memory tile. This results in the addition of a charge to the edge capacitor.

At step 240, embodiments convert the new capacitor charge to a second digital value using the ADC. Embodiments may store the second digital value in digital memory.

At step 250, embodiments process the first and second digital values, determining an average of the two values. Embodiments store the average value is digital memory and provide the average as an output for downstream use at step 260.

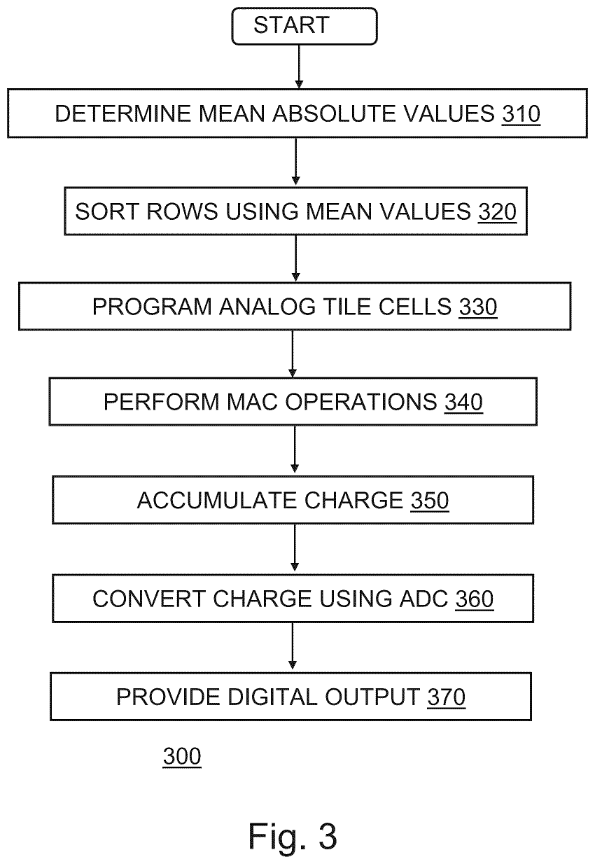

FIG. 3 provides a flowchart 300, illustrating exemplary activities associated with the practice of the disclosure. After program start, at step 310, embodiments determine a mean value for each row of data in a matrix using absolute values for the individual elements of the row, yielding a set of mean values, one mean value for each row of the matrix of data.

At step 320, embodiments order the rows of the matrix according to the mean values of the rows. In one embodiment, the rows are ordered from the largest magnitude mean value to the smallest magnitude mean value.

At step 330, embodiments program the memory cells of at least one analog memory tile of analog memory cells using the values of the data matrix as reordered. In this embodiment, the rows of the analog tile are programmed with the values corresponding the data matrix rows such that the method programs the first row of the tile with the values of the data matrix row having the largest magnitude mean value and so on until programming the last programmed row of the analog tile with the values of the row of the data matrix having the smallest magnitude mean value. In one embodiment, the order may be reversed such that the first row of the tile receives the values of the data matrix row having the smallest mean value magnitude and the last programmed row of the analog tile receives the values of the row of the data matrix having the largest mean value magnitude.

At step 340, embodiments process the cells of the analog memory tile(s), by reading the values of the cells of each row, thereby performing a MAC operation on the cells of the row.

At step 350, embodiments accumulate charges in one or more edge capacitors due to the MAC operations on the analog memory tile rows.

At step 360, embodiments convert the accumulated charges of the edge capacitors of the tiles using ADC circuits.

At step 370, embodiments store the digital output of the ADC in digital memory and provide the digital value as an output for downstream use. In one embodiment, the digital output of the ADC represents the Multiply And Accumulate result, in other words the product between the input activation vector and the weight matrix. This result is used downstream as an input to subsequent computing blocks such as activation function, neural network classification and other cases.

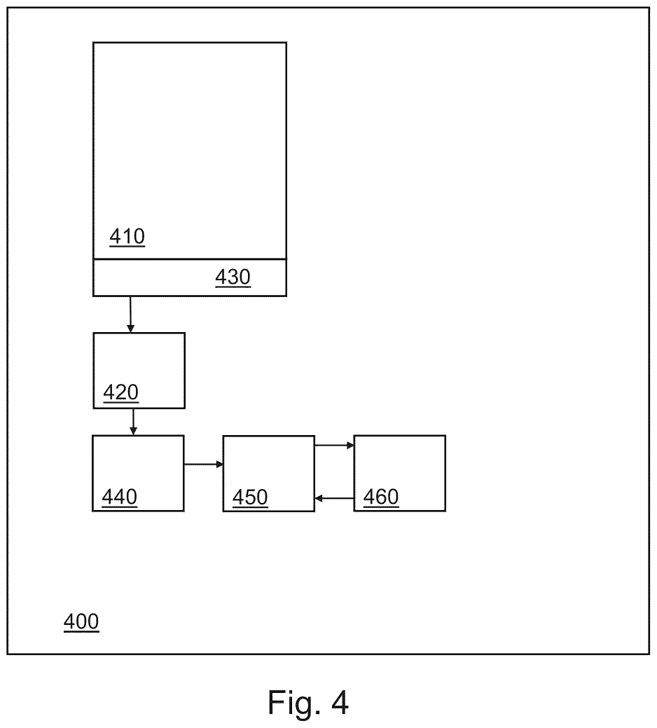

FIG. 4 provides a schematic illustration of system details according to an embodiment of the invention. As shown in the figure, system 400, includes an analog memory tile 410. In one embodiment, the analog tile comprises an array of analog memory cells such as phase change memory cells. Each cell of the array may be programmed with an analog data value from a data matrix or other input source of analog data. The cells may be written to, read, and erased for reuse in subsequent write-read cycles.

System 400 also includes one or more edge capacitors 420. The configuration of edge capacitors 420 enables the capacitors to accumulate charge as MAC operations are applied to the cells and rows of the analog memory tile 410.

System 400 also include optional analog current source 430. In one embodiment, analog current source 430 includes a row of ROM in parallel with the rows of the analog memory tile. The Rom may be read by applying an appropriate excitation voltage. Reading the ROM applies an additional charge to system edge capacitors 420.

System 400 also includes ADC 440 coupled to the edge capacitor and configured to convert the analog charge of the capacitor 420 to a digital value. Embodiments then store the digital value in digital memory 450, such as volatile memory 112 described above.

System 400 also includes a processor 460, such as processor set 110, described above. Processor 460 receives digital values from memory 450 and ADC 440 and determines final output values for downstream use.

It is to be understood that although this disclosure includes a description on cloud computing, implementation of the teachings recited herein are not limited to a cloud computing environment. Rather, embodiments of the present invention are capable of being implemented in conjunction with any other type of computing environment now known or later developed.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, or media, as those terms are used in the present disclosure, explicitly excludes storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage medium or device as transitory because the data is not transitory while it is stored.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions collectively stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer implemented method for analog to digital conversion the method comprising:
converting a charge of a capacitor from an analog value to a first digital value;
storing the first digital value;
adding an electrical charge to the capacitor, yielding an enhanced capacitor charge;
converting the enhanced capacitor charge from an analog value to a second digital value;
determining an average of the first digital value and the second digital value; and
providing the average as an output.

2. The computer implemented method according to claim 1, further comprising:
determining a mean vale for each row of a first matrix of values comprising a plurality of rows according to absolute values of weights in the row, yielding a plurality of mean values;
ordering the rows of the first matrix according to the plurality of mean values;
programming a tile of analog memory cells according to values of the ordered rows;
performing a multiply and accumulate (MAC) operation to each row of the tile;
accumulating charge on the capacitor according to the MAC operations.

3. The computer implemented method according to claim 2, wherein ordering the rows comprises ordering the rows from a largest magnitude mean value to a smallest magnitude mean value.

4. The computer implemented method according to claim 2, further comprising:
programming a plurality of tiles of analog memory cells according to values of the ordered rows;
performing a multiply and accumulate (MAC) operation to each row of the tiles;
accumulating charge on a capacitor for each tile of the plurality according to the MAC operations;
converting the charge on the capacitor for each tile to a per tile digital value;
summing the per tile digital values; and
providing the sum as an output.

5. The computer implemented method according to claim 1, wherein the electrical charge comprises about half a bin of charge.

6. The computer implemented method according to claim 1, wherein the electrical charge is determined according to an analog to digital converter precision.

7. The computer implemented method according to claim 1, wherein adding an electrical charge to the capacitor, yielding an enhanced capacitor charge comprises adding electrical charge using an analog current source.

8. The computer implemented method according to claim 7, wherein the analog current source comprises read-only-memory.

9. The computer implemented method according to claim 1, wherein adding an electrical charge to the capacitor, yielding an enhanced capacitor charge comprises applying a voltage to a resistor in a circuit with the capacitor.

10. The computer implemented method according to claim 1, wherein storing the first digital value comprises storing the first digital value in a digital memory.

11. The computer implemented method according to claim 1, further comprising:
applying an excitation voltage to an array of analog memory cells; and
accumulating the charge resulting from the excitation voltage in the capacitor.

12. The computer implemented method according to claim 11, further comprising:
mapping values from a data set to cells of the array.

13. The computer implemented method according to claim 1, further comprising storing the second digital value.

14. The computer implemented method according to claim 1, further comprising determining the average of the first digital value and the second digital value using a digital processor.

15. A computer implemented method for analog to digital conversion the method comprising:
determining a mean vale for each row of a first matrix of values comprising a plurality of rows according to absolute values of weights in the row, yielding a plurality of mean values;
ordering the rows of the first matrix according to the plurality of mean values;
programming a tile of analog memory cells according to values of the ordered rows;
performing a multiply and accumulate (MAC) operation to each row of the tile;
accumulating charge on a capacitor according to the MAC operations;
converting an analog charge of the capacitor to a digital value; and
storing the digital value.

16. The computer implemented method according to claim 15, further comprising:
ordering the rows from a largest magnitude mean value to a smallest magnitude mean value.

17. The computer implemented method according to claim 15, further comprising:
programming a plurality of tiles comprising analog memory cells according to values of the ordered rows;
performing a multiply and accumulate (MAC) operation to each row of the tiles;
accumulating charge on a capacitor for each tile of the plurality according to the MAC operations;
converting the charge on the capacitor for each tile to a per tile digital value;
summing the per tile digital values;
storing the sum of the per tile digital values; and
providing the sum as an output.

18. A system for analog to digital conversion: the system comprising:
an array of analog memory cells;
an analog current source disposed in parallel with rows of the array;
a capacitor disposed in series with the array and the analog current source;
an analog to digital converter (ADC) disposed to read a charge of the capacitor;
a digital memory disposed to receive an ADC output; and
a digital processor disposed to receive ADC and digital memory outputs.

19. The system according to claim 18, wherein the analog current source comprises a row of read only memory.

20. The system according to claim 18, wherein the analog memory cells comprises phase change memory cells.
